(19) United States
(12) Patent Application Publication
(10) Pub. No.: US 2024/0063331 A1
(43) Pub. Date: Feb. 22, 2024

(54) OPTOELECTRONIC SEMICONDUCTOR COMPONENT AND METHOD FOR PRODUCING AN OPTOELECTRONIC SEMICONDUCTOR COMPONENT

(71) Applicant: ams-OSRAM International GmbH, Regensburg (DE)

(72) Inventors: Stefan ILLEK, Donaustauf (DE); Heng WANG, Eriskirch (DE)

(73) Assignee: ams-OSRAM International GmbH, Regensburg (DE)

(21) Appl. No.: 18/260,949

(22) PCT Filed: Dec. 20, 2021
(86) PCT No.: PCT/EP2021/086823

§ 371 Date: Jul. 11, 2023

(30) Foreign Application Priority Data
Jan. 13, 2021 (DE) 102021100534.5

(51) Int. Cl. H01L 33/02; H01L 33/14; H01L 33/30; H01L 33/00

(52) U.S. Cl. CPC H01L 33/025; H01L 33/14; H01L 33/305; H01L 33/0062

(57) ABSTRACT

The invention relates to an optoelectronic semiconductor component that includes a semiconductor body with a first injection region, in which a first protection region is formed, a second injection region, in which a second protection region is formed, and an active region, which is designed to generate electromagnetic radiation and which is arranged between the first injection region and the second injection region. The first injection region and the first protection region have a first conductivity type, and the second injection region and the second protection region have a second conductivity type. The first protection region extends along a lateral surface of the semiconductor body from a first injection region face facing away from the active region into the second injection region and completely passes through the active region. The invention additionally relates to a method for producing an optoelectronic semiconductor component.

### CROSS-REFERENCE TO RELATED APPLICATIONS

The present application is a national stage entry from International Application No. PCT/EP2021/086823, filed on Dec. 20, 2021, published as International Publication No. WO 2022/152519 A1 on Jul. 21, 2022, and claims priority to German Patent Application No. 10 2021 100 534.5, filed Jan. 13, 2021, the disclosures of all of which are hereby incorporated by reference in their entireties.

### FIELD OF THE INVENTION

An optoelectronic semiconductor component and a method for producing an optoelectronic semiconductor component are disclosed.

### BACKGROUND OF THE INVENTION

In particular, the optoelectronic semiconductor component is intended to generate and/or detect electromagnetic radiation, preferably light that is perceptible to the human eye.

A problem to be solved is to specify an optoelectronic semiconductor component that exhibits improved efficiency.

Another problem to be solved is to provide a method for simplified fabrication of an optoelectronic semiconductor component with improved efficiency.

### SUMMARY OF THE INVENTION

According to at least one embodiment, the optoelectronic semiconductor component comprises a semiconductor body having a first injection region in which a first protection region is formed and a second injection region in which a second protection region is formed.

The semiconductor body comprises in particular a plurality of epitaxially grown layers of a semiconductor material. The layers are deposited on top of each other in a stacking direction. The stacking direction thus runs transversely, in particular perpendicularly, to a main direction of extension of the semiconductor body. For example, the semiconductor body is a monolithically formed semiconductor crystal.

The first injection region is a region of the semiconductor body that is intended for the injection of charge carriers. For example, injection of holes into the semiconductor body is performed by means of the first injection region. The first protection region is formed in the first injection region. In particular, the first injection region is a region of the semiconductor body into which a first doping material is introduced.

The second injection region is another region of the semiconductor body that is intended for injection of charge carriers. For example, an injection of electrons into the semiconductor body is performed by means of the second injection region. The second protection region is formed in the second injection region. In particular, the second injection region is a further region of the semiconductor body into which a second doping material is introduced.

By means of the first protection region and the second protection region, a preferential distribution of a charge carrier density in the semiconductor body can be generated during operation of the optoelectronic semiconductor component.

Further, the semiconductor body comprises an active region arranged to generate electromagnetic radiation and disposed between the first injection region and the second injection region. The active region has, for example, a pn junction and a double heterostructure for radiation generation or radiation detection. The semiconductor component is, for example, a luminescent diode, in particular a light-emitting diode or a laser diode. The first injection region and the second injection region are provided here for injecting charge carriers into the active region.

According to at least one embodiment of the optoelectronic semiconductor component, the first injection region and the first protection region have a first conductivity type. A conductivity type can be generated by doping a semiconductor material with impurity atoms. For example, the first conductivity is a p-type conductivity in which majority charge carriers are provided by holes. Preferably, the first injection region and the first protection region differ in a concentration of the dopants.

According to at least one embodiment of the optoelectronic semiconductor component, the second injection region and the second protection region have a second conductivity type. For example, the second conductivity is an n-type conductivity in which the majority charge carriers are provided by electrons. Preferably, the second injection region and the second protection region differ in a concentration of the dopants. In particular, the second conductivity type is different from the first conductivity type.

According to at least one embodiment of the optoelectronic semiconductor component, a dopant concentration in the first protection region is higher than in the first injection region.

A higher dopant concentration can locally influence a charge carrier density during operation of the optoelectronic semiconductor component. For example, a higher dopant concentration in the first protection region decreases a density of minority charge carriers in the first protection region. Hereby, the charge carrier density can be selectively reduced in regions where the efficiency of the semiconductor component is reduced by non-radiative recombination processes.

According to at least one embodiment of the optoelectronic semiconductor component, a dopant concentration in the second protection region is higher than in the second injection region. An increased dopant concentration in the second protection region may influence an extension of the first protection region in the stacking direction. In particular, an increased dopant concentration in the second protection region reduces an extension of the first protection region parallel to the stacking direction in the direction of the second protection region.

According to at least one embodiment of the optoelectronic semiconductor component, the second protection region is arranged on a side of the second injection region facing away from the active region. By an arrangement on the side of the second injection region facing away from the active region, an extension of the first protection region in the stacking direction can be controlled in a targeted and comparatively simple manner.

According to at least one embodiment of the optoelectronic semiconductor component, the first protection region extends along a lateral surface of the semiconductor body from a side of the first injection region facing away from the active region into the second injection region and completely penetrates the active region. The lateral surface extends along the stacking direction of the semiconductor body, or transverse to the main extension direction of the semiconductor body. For example, the lateral surface can be arranged at an angle, in particular between 60° and 70°, to the main extension direction, resulting in a trapezoidal cross-section of the semiconductor body. Going further, the lateral surface can also be arranged parallel to the stacking direction or perpendicular to the main extension direction of the semiconductor body. Preferably, the lateral surface of the semiconductor body, especially preferably the lateral surface in the active region, is completely covered by the first protection region.

Here, use is made of the knowledge that the lateral surfaces of a semiconductor body can be a source of non-radiative recombination processes. By covering the lateral surfaces with the first protection region, a charge carrier density at the lateral surface can be reduced, and thus a probability for non-radiative recombination processes can also be reduced. For example, the first protection region surrounds the semiconductor body at least partially in a lateral direction. Preferably at least in the region of the active region.

In particular, a band gap of the active region is locally enlarged in the first protection region by means of quantum well intermixing in the active region. In operation, the minority charge carrier density is thereby correspondingly locally reduced. Advantageously, non-radiative recombination at the lateral surface near the first protection region can thus be reduced.

According to at least one embodiment of the optoelectronic semiconductor component, the optoelectronic semiconductor component comprises:
a semiconductor body having a first injection region in which a first protection region is formed, a second injection region in which a second protection region is formed, and an active region intended to generate electromagnetic radiation and disposed between the first injection region and the second injection region, wherein
the first injection region and the first protection region have a first conductivity type,
the second injection region and the second protection region have a second conductivity type
a dopant concentration in the first protection region is higher than in the first injection region,
a dopant concentration in the second protection region is higher than in the second injection region,
the second protection region is arranged on a side of the second injection region facing away from the active region, and
the first protection region extends along a lateral surface of the semiconductor body from a side of the first injection region facing away from the active region into the second injection region and completely penetrates the active region.

An optoelectronic semiconductor component described here is based on the following considerations, among others: undesired non-radiative recombination effects can occur at the lateral surfaces of a semiconductor body. This effect is particularly significant in red emitting μLED's based on an indium gallium aluminum phosphide semiconductor material, since this material has a high surface recombination velocity and a large charge carrier diffusion length. These properties produce a high non-radiative recombination probability at the lateral surfaces of the semiconductor body. This effect increases with decreasing lateral expansion of the semiconductor body, since smaller bodies have proportionally more lateral surfaces per volume.

The optoelectronic semiconductor component described herein makes use of, among other things, the idea of introducing a first protection region along a lateral surface of the semiconductor body in first and second injection regions. The first protection region reduces a carrier density at the lateral surface of the semiconductor body. Thus, a non-radiative recombination probability can be reduced. As a result, the efficiency of the optoelectronic semiconductor component is advantageously increased.

According to at least one embodiment of the optoelectronic semiconductor component, the semiconductor body is based on a phosphide compound semiconductor material, in particular InGaAlP or an arsenide compound semiconductor material, in particular AlGaAs. These semiconductor materials exhibit a particularly high surface recombination rate, which is why countermeasures with regard to non-radiative recombination are particularly useful.

“Phosphide compound semiconductor material based” in this context means that the semiconductor body or at least part thereof, particularly preferably at least the active region and/or a growth substrate wafer, preferably comprises AlₙGaₘIn₁₋ₙ₋ₘP or AsₙGaₘIn₁₋ₙ₋ₘP, wherein 0≤n≤1, 0≤m≤1 and n+m≤1. In other words, the semiconductor body or at least a part thereof, especially preferably at least the active region and/or a growth substrate wafer is comprises (InGa₁₋ₓAlₓ)_{y}P_{1-y}. Thereby, this material does not necessarily have to have a mathematically exact composition according to the above formula. Rather, it may comprise one or more dopants as well as additional constituents. For the sake of simplicity, however, the above formula contains only the essential components of the crystal lattice (Al or As, Ga, In, P), even if these may be replaced in part by small amounts of other substances.

“Arsenide compound semiconductor material based” in this context means that the semiconductor body or at least a part thereof, particularly preferably at least the active region and/or a growth substrate wafer, preferably comprises AlₙGaₘIn₁₋ₙ₋ₘAs, wherein 0≤n≤1, 0≤m≤1 and n+m≤1. This material does not necessarily have to have a mathematically exact composition according to the above formula. Rather, it may comprise one or more dopants as well as additional constituents. For the sake of simplicity, the above formula includes only the essential components of the crystal lattice (Al or As, Ga, In), even if these may be partially replaced by small amounts of other substances.

According to at least one embodiment of the optoelectronic semiconductor component, a shielding region is arranged between the first protection region and the second protection region. The shielding region is, for example, an epitaxially grown region of the semiconductor body. In particular, the shielding region has the second conductivity type.

Preferably, the shielding region is formed with a semiconductor material having a lower surface recombination velocity than the material of the second injection region. A low surface recombination velocity can advantageously reduce a probability of non-radiative recombination, thereby increasing an efficiency of the optoelectronic semiconductor component. In particular, the surface recombination velocity in the shielding region has a value of 1*10⁴ cm/s to 1*10⁶ cm/s, preferably the surface recombination velocity in the shielding region has a value of less than 1*10⁵ cm/s.

According to at least one embodiment of the optoelectronic semiconductor component, the shielding region has a lower aluminum content than the second injection region. In particular, in layers based on a phosphide compound semiconductor material or an arsenide compound semiconductor material, a reduced surface recombination speed can be achieved by a lower aluminum content.

According to at least one embodiment of the optoelectronic semiconductor component, the shielding region has a composition according to the formula (InGa₁₋ₓAlₓ)_{0.49}P_{0.51}, wherein 0.5≤x≤0.9, preferably 0.6≤x≤0.8, and particularly preferably x=0.6. Such a composite shielding region advantageously exhibits a particularly low surface recombination velocity.

According to at least one embodiment of the optoelectronic semiconductor component, the shielding region has a lower surface recombination velocity than the second injection region. By means of a lower surface recombination velocity, a non-radiative recombination probability is advantageously reduced in the shielding region.

According to at least one embodiment of the optoelectronic semiconductor component, the dopant concentration in the shielding region is at least a factor of 2 higher, preferably at least a factor of 4 higher, than the dopant concentration in the first protection region. By means of the dopant concentration in the shielding region, it is possible, among other things, to set how far the first protection region extends into the second injection region. If the dopant concentration in the shielding region is a factor of 2 to 4 higher, the first protection region advantageously ends in the shielding region.

According to at least one embodiment of the optoelectronic semiconductor component, the first protection region ends within the shielding region. The shielding region has a particularly low surface recombination speed. If the first protection region ends in the shielding region, an advantageously reduced non-radiative recombination probability results for a pn junction formed there, due to the low surface recombination velocity of the material of the shielding region.

According to at least one embodiment of the optoelectronic semiconductor component, the first protection region is arranged outside a core region. The core region extends centrally in the semiconductor body and runs in particular parallel to the stacking direction. The core region is thus spaced apart from the lateral surfaces of the semiconductor body in regions and preferably on all sides. In the core region, for example, a higher charge carrier density is present than in the first protection region.

According to at least one embodiment of the optoelectronic semiconductor component, the dopant concentration in the second protection region is at least a factor of 2 higher, preferably at least a factor of 4 higher, than the dopant concentration in the first protection region. For example, the dopant concentration in the second protection region is between 4*10¹⁷ cm⁻³ and 10*10¹⁷ cm⁻³. The dopant concentration in the second protection region can be used, among other things, to set how far the first protection region extends into the second injection region. At a dopant concentration that is higher by a factor of 2 to 4, the first protection region advantageously ends in the shielding region.

According to at least one embodiment of the optoelectronic semiconductor component, the first injection region and the second injection region are each based on a material having a composition according to the formula (InGa₁₋ₓAlₓ)_{0.49}P_{0.51} wherein x=1. Such a composition is advantageous for forming an optoelectronic semiconductor component intended to emit electromagnetic radiation in the red spectral region.

According to at least one embodiment of the optoelectronic semiconductor component, the first protection region is doped with one of the following materials: Magnesium, Zinc. As a dopant for the first protection region, an impurity atom is optimal that can change a doping level in the first protection region and has a diffusion rate that is as high as possible. The diffusion rate of zinc is particularly high, which is why zinc is preferably used. The second protection region is doped with one of the following materials, for example: Tellurium, Silicon.

According to at least one embodiment of the optoelectronic semiconductor component, the active region is formed as a quantum well structure, preferably as a multi-quantum well structure. A quantum well structure is, for example, a single quantum well structure (SQW) or a multi-quantum well structure (MQW). By means of a quantum well structure, a particularly efficient radiative recombination of charge carriers can be achieved. In addition, a band gap in a quantum well structure can be influenced particularly easily by quantum well intermixing.

According to at least one embodiment of the optoelectronic semiconductor component, the active region is intended to emit electromagnetic radiation in a wavelength range from 580 nm to 1 μm, preferably in a wavelength range from 580 nm to 660 nm. For semiconductor components with an emission spectrum of 580 nm to 660 nm, an aluminum content in this material is usually particularly high. This leads to a disadvantageously high surface recombination speed, which is why measures against non-radiative recombination processes are particularly useful.

According to at least one embodiment of the optoelectronic semiconductor component, a lateral extension of the semiconductor body is less than 100 μm, preferably less than 50 μm and particularly preferably less than 20 μm. The lateral extension describes an extension of the semiconductor body in a direction parallel to the main extension direction and transverse to the stacking direction of the semiconductor body. A small lateral extension enables, for example, use of the optoelectronic semiconductor component as a pixel in a high-resolution display device.

A method for producing an optoelectronic semiconductor component is further disclosed. The optoelectronic component can be produced in particular by means of a method described herein. That is, all features disclosed in connection with the method for producing an optoelectronic semiconductor component are also disclosed for the optoelectronic semiconductor component, and vice versa.

According to at least one embodiment of the method for producing an optoelectronic semiconductor component, in a step A) a semiconductor body is provided having a first injection region, a second injection region in which a second protection region is formed, and an active region intended for generating electromagnetic radiation and arranged between the first injection region and the second injection region, wherein
the first injection region has a first conductivity type,
the second injection region and the second protection region have a second conductivity type,
a dopant concentration in the second protection region is higher than in the second injection region, and
the second protection region is arranged on a side of the second injection region facing away from the active region.

Preferably, a plurality of semiconductor bodies are provided in a wafer composite. For example, the semiconductor bodies are part of a continuous semiconductor layer sequence.

According to at least one embodiment of the method for producing an optoelectronic semiconductor component, in a step B) a mask region is applied to a side of the first injection region facing away from the active region, the mask region having a smaller lateral extension than the first injection region and being arranged centrally on the first injection region, as seen in a top view. Preferably, the mask region completely covers a core region of the semiconductor body.

In particular, the mask region is only weakly permeable or not permeable to a material introduced as a dopant into the first injection region. Thus, advantageously, the introduction of the first dopant can be limited to a region outside the core region of the semiconductor body. For example, the mask material is applied to the entire surface of the semiconductor body. In particular, the mask region is patterned in a photolithographic process. Preferably, a plurality of mask regions is arranged in parallel on a plurality of semiconductor bodies in a wafer compound and patterned in a common process step.

According to at least one embodiment of the method for producing an optoelectronic semiconductor component, in a step C) a first dopant material is introduced into the first injection region to form a first protection region with the first conductivity type, which extends along a lateral surface of the semiconductor body from the side of the first injection region facing away from the active region into the second injection region and completely penetrates the active region, a dopant concentration in the first protection region being higher than in the first injection region. For example, the first dopant material is introduced into the first injection region by implantation.

The diffusion depth of the first dopant is largely determined by the level of doping in the second protection region. The vertical expansion of the first protection region can be adjusted in a controlled manner by a suitable choice of the doping level in the second protection region.

The introduction of the first dopant material is at least partially shielded by the mask region, so that penetration of the first dopant material into the core region is reduced or avoided. Thus, the first protection region is formed especially on the lateral surfaces of the semiconductor body outside the core region.

According to at least one embodiment of the method for producing an optoelectronic semiconductor component, step C) is carried out in such a way that a band gap of the active region in the first protection region is enlarged by quantum well intermixing. Due to a locally enlarged band gap in the active region, a reduction of the charge carrier density at the lateral surfaces of the semiconductor body can be achieved during operation of the semiconductor component. Thus, non-radiative recombination at the lateral surfaces of the semiconductor body is advantageously reduced or avoided.

The generation of sufficient quantum well intermixing depends, for example, on a time duration of the process step C). For example, sufficient quantum well intermixing in the active region in the first protection region advantageously occurs for a time duration of more than 4 minutes. Step C) preferably takes place over a time duration of at least 15 minutes and particularly preferably of at least 45 minutes.

According to at least one embodiment of the process for producing an optoelectronic semiconductor component, the introduction of the first dopant material in step C) is carried out by means of diffusion. Diffusion enables a particularly gentle introduction of dopant material which does not produce any radiation damage in the crystal lattice of the semiconductor body.

According to at least one embodiment of the method for producing an optoelectronic semiconductor component, a semiconductor body is provided in step A), which additionally has a shielding region between the first protection region and the second protection region. The shielding region is formed in particular with a semiconductor material which is epitaxially grown. The shielding region has in particular the second conductivity type.

Preferably, the shielding region is formed with a semiconductor material having a lower surface recombination velocity than the material of the second injection region. A low surface recombination velocity can advantageously reduce a probability of non-radiative recombination, thereby increasing an efficiency of the optoelectronic semiconductor component. In particular, the surface recombination velocity in the shielding region has a value of 1*10⁴ cm/s to 1*10⁶ cm/s, preferably the surface recombination velocity in the shielding region has a value of less than 1*10⁵ cm/s.

According to at least one embodiment of the method for producing an optoelectronic semiconductor component, in step C), the first dopant material is introduced into the first injection region to form a first protection region having the first conductivity type, such that the first protection region extends along a lateral surface of the semiconductor body from the side of the first injection region facing away from the active region into the shielding region and completely penetrates the active region, wherein a dopant concentration in the shielding region is higher than in the first protection region.

The dopant concentration in the shielding region can be used, among other things, to set how far the first protection region extends into the second injection region. With a dopant concentration in the shielding region that is higher by a factor of 2 to 4, the first protection region advantageously ends in the shielding region.

According to at least one embodiment of the method for producing an optoelectronic semiconductor component, a final geometry of the optoelectronic semiconductor component is defined in a subsequent step D) by common structuring processes for the generation of the lateral surfaces. For example, a lateral surface has an angle between 60° and 70° to the main extension direction of the semiconductor body.

An optoelectronic semiconductor component described here is particularly suitable for use as μLED in a display device, for example a display.

### BRIEF DESCRIPTION OF THE DRAWINGS

Further advantages and advantageous embodiments and further embodiments of the optoelectronic semiconductor component result from the following exemplary embodiments shown in connection with the figures.

Showing in:

FIG. 1 a schematic sectional view of an optoelectronic semiconductor component described herein according to a first exemplary embodiment,

FIG. 2 a schematic sectional view of an optoelectronic semiconductor component described herein according to a second exemplary embodiment,

FIG. 3 a schematic top view of an optoelectronic semiconductor component described herein according to the first exemplary embodiment, and

FIG. 4 a schematic representation of a dopant concentration as well as a variation of a band gap along a stacking direction of an optoelectronic semiconductor component described herein according to the second exemplary embodiment.

### DETAILED DESCRIPTION

Elements that are identical, similar or have the same effect are given the same reference signs in the figures. The figures and the proportions of the elements shown in the figures are not to be regarded as to scale. Rather, individual elements may be shown exaggeratedly large for better representability and/or for better comprehensibility.

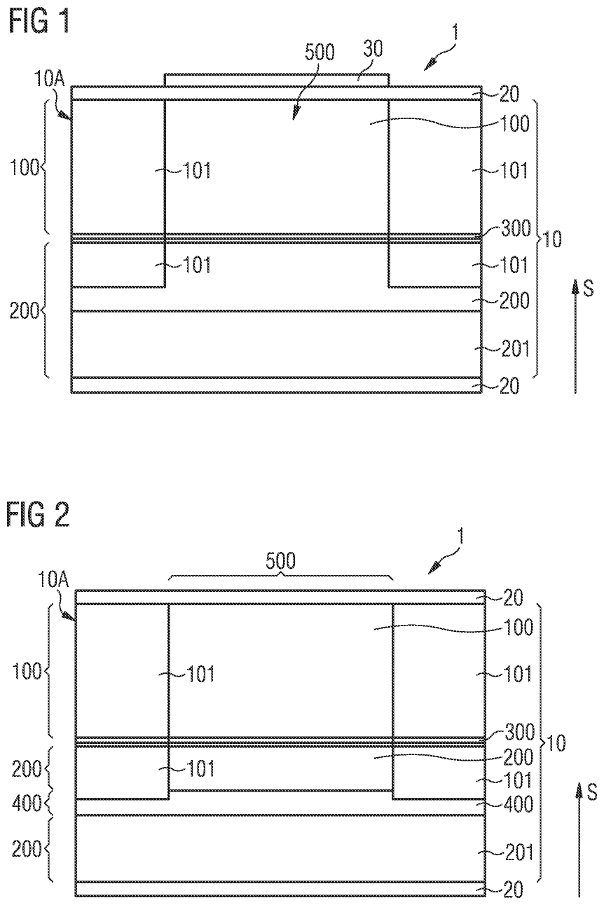

FIG. 1 shows a schematic sectional view of an optoelectronic semiconductor component 1 described herein according to a first exemplary embodiment. The optoelectronic semiconductor component 1 includes a semiconductor body 10 having, along a stacking direction S, a second protection region 201 in which a second injection region 200 is formed, an active region 300, and a first injection region 100 in which a first protection region 101 is formed.

An electrical contact 20 is arranged on a side of the first injection region 100 facing away from the active region 300. Furthermore, an electrical contact 20 is arranged on a side of the second protection region 201 facing away from the active region 300. The electrical contacts 20 are formed with a metal. By means of the electrical contacts 20, an electrical connection of the optoelectronic semiconductor component 1 and an injection of charge carriers into the semiconductor body 10 are performed.

A mask region 30 is arranged on the electrical contact 20 facing the first injection region 100. The mask region 30 is in particular little- or non-permeable to a first doping material with which the first protection region 101 is doped. The mask region 30 can be removed in a further process step and is then no longer included in the finished, optoelectronic semiconductor component 1.

The stacking direction S extends transversely, in particular perpendicularly, to the main extension direction of the active region 300. The semiconductor body 10 has a lateral surface 10A extending parallel to the stacking direction S. The first protection region 101 extends along the lateral surface 10A of the semiconductor body 10 in the first injection region 100 into the second injection region 200, completely penetrating the active region 300.

The first injection region 100 and the first protection region 101 have a first conductivity type. The second injection region 200 and the second protection region 201 have a second conductivity type. For example, the first conductivity type is a p-type conductivity and the second conductivity type is an n-type conductivity.

The level of dopant concentration in the second protection region 201 influences the extent of the first protection region 101 in the stacking direction S. Advantageously, the dopant concentration of the second protection region 201 is selected such that the first protection region 101 ends in the second injection region 200.

In the center of the semiconductor body 10, seen in a top view parallel to the stacking direction S, there is a core region 500 which is free of the first protection region 101. The core region 500 is spaced on all sides from the lateral surfaces 10A of the semiconductor body 10. The core region 500 is at least partially covered by the shielding region 30. The lateral extent of the first protection region 101 is adjustable by means of the lateral extent of the shielding region 30.

In the first protection region 101, a band gap of the active region 300 is locally enlarged by means of quantum well intermixing in the active region 300. Thus, a lateral diffusion of charge carriers in the active region 300 toward the lateral surfaces 10A is reduced. Thus, a lower carrier concentration at the lateral surfaces 10A is generated in the active region 300. As a result, a non-radiative recombination probability in the optoelectronic semiconductor component 1 is advantageously reduced.

FIG. 2 shows a schematic sectional view of an optoelectronic semiconductor component 1 described herein according to a second exemplary embodiment. The second exemplary embodiment corresponds essentially to the first exemplary embodiment. In contrast, in the second exemplary embodiment shown in FIG. 2, the semiconductor body 10 additionally comprises a shielding region 400 arranged between the first protection region 101 and the second protection region 201 and having the second conductivity type.

The shielding region 400 is formed with a material having a lower proportion of aluminum than the second injection region 200. Due to the lower proportion of aluminum in the shielding region 400, a surface recombination velocity in the shielding region 400 is advantageously reduced. Therefore, there is a lower probability of non-radiative recombination in the shielding region 400.

The level of the dopant concentrations in the shielding region 400 and the second protection region 201 influence the extent of the first protection region 101 in the stacking direction S. Advantageously, the dopant concentration of the shielding region 400 is selected such that the first protection region 101 ends in the shielding region 400. Further, the dopant concentration in the second injection region 200 is sufficiently low. For example, the dopant concentration in the second injection region 200 is lower than the dopant concentration in the first protection region 101. In contrast, the dopant concentration in the shielding region 400 is preferably at least a factor of 2 higher, preferably at least a factor of 4 higher, than the dopant concentration in the first protection region 101.

By virtue of the fact that the first protection region 101 ends in the shielding region 400, a pn junction formed there advantageously exhibits a particularly low probability of non-radiative surface recombination events.

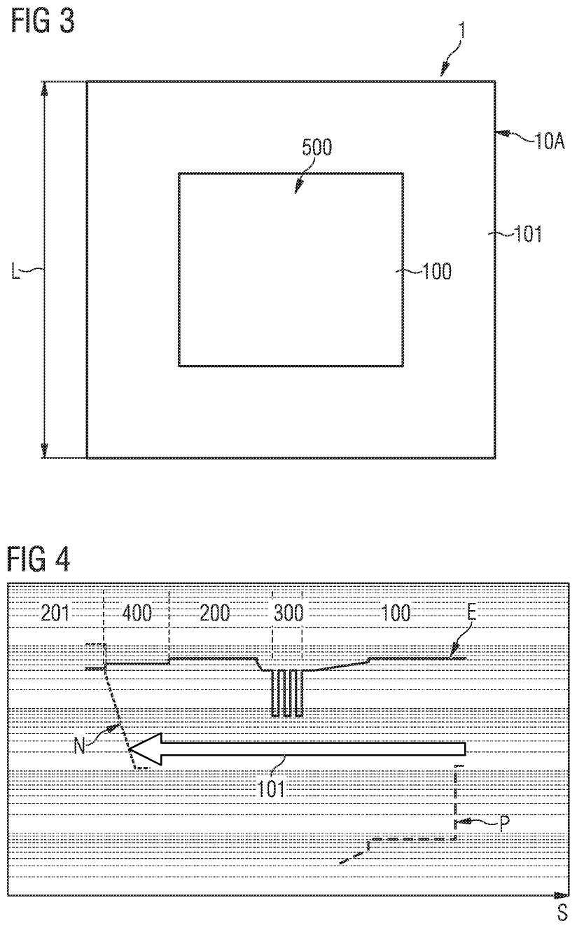

FIG. 3 shows a schematic top view of an optoelectronic semiconductor component 1 described herein according to the first exemplary embodiment. In the top view, a lateral extension L of the semiconductor body 10 is apparent. The lateral extension L extends from a lateral surface 10A of the semiconductor body 10 to an opposite lateral surface 10A of the semiconductor body 10. The semiconductor body 10 does not necessarily have a square or rectangular shape. For example, the lateral extension L can also be regarded as a diameter of a round semiconductor body 10.

In the top view of the semiconductor body 10, the injection region 100 and the first protection region 101 are visible. In the center of the semiconductor body 10, the core region 500 is shown which is free from the first protection region 101. The core region 500 is completely surrounded by the first protection region 101 in a lateral direction and is spaced from the lateral surfaces 10A of the semiconductor body 10 on all sides. Thus, all lateral surfaces 10A of the semiconductor body 10 are covered by the first protection region 101. As a result, the non-radiative recombination probability at the lateral surfaces 10A is advantageously reduced.

FIG. 4 shows a schematic representation of an n-dopant concentration N, a p-dopant concentration P, and a variation of a band gap E along a stacking direction S of an optoelectronic semiconductor component 1 described herein according to the second embodiment.

Along the stacking direction S, the course of the band gap E is shown over the second protection region 201, the shielding region 400, the second injection region 200, the active region 300 and the first injection region 100. A plurality of layers with different band gaps E are present in the active region 300.

The n-dopant concentration N assumes a maximum value within the second protection region 201 and steadily decreases in the course of the shielding region 400 along the stacking direction S. The p-dopant concentration P has a maximum value within the first injection region 100 and steadily decreases in the course against the stacking direction S in the direction of the active region 300. Within the first protection region 101, the p-dopant concentration P has a higher value than in the first injection region 100 and thus extends counter to the stacking direction S through the active region 300 and partially through the second injection region 200 into the shielding region 400.

The maximum value of the n-dopant concentration N in the second protection region 201 is higher by at least a factor of 2, preferably by at least a factor of 4, than the value of the p-dopant concentration P in the first protection region 101, thus ensuring that the extension of the first protection region 101 against the stacking direction S ends within the shielding region 400.

The invention is not limited by the description based on the exemplary embodiments. Rather, the invention encompasses any new feature as well as any combination of features, which in particular includes any combination of features in the patent claims, even if this feature or combination itself is not explicitly stated in the patent claims or exemplary embodiments.

1. An optoelectronic semiconductor component comprising
a semiconductor body having a first injection region in which a first protection region is formed, a second injection region in which a second protection region is formed, and an active region intended to generate electromagnetic radiation and arranged between the first injection region and the second injection region, wherein
the first injection region and the first protection region have a first conductivity type,
the second injection region and the second protection region have a second conductivity type,
a dopant concentration in the first protection region is higher than in the first injection region,
a dopant concentration in the second protection region is higher than in the second injection region,
the second protection region is arranged on a side of the second injection region facing away from the active region, and
the first protection region extends along a lateral surface of the semiconductor body from a side of the first injection region facing away from the active region into the second injection region and completely penetrates the active region.

2. The optoelectronic semiconductor component according to the preceding claim 1,
wherein the semiconductor body is based on a phosphide compound semiconductor material, in particular InGaAlP or an arsenide compound semiconductor material, in particular AlGaAs.

3. The optoelectronic semiconductor component according to claim 1,
in which a shielding region is arranged between the first protection region and the second protection region.

4. The optoelectronic semiconductor component according to claim 3,
wherein the shielding region comprises a smaller proportion of aluminum than the second injection region.

5. The optoelectronic semiconductor component according to claim 3,
in which the shielding region has a composition according to the formula (InGa₁₋ₓAlₓ)_{0.49}P_{0.51}, wherein 0.5≤x≤0.9, preferably 0.6≤x≤0.8, and particularly preferably x=0.6.

6. The optoelectronic semiconductor component according to claim 3,
wherein the shielding region has a lower surface recombination speed than the second injection region.

7. The optoelectronic semiconductor component according to claim 3,
in which a dopant concentration in the shielding region is at least a factor 2 higher, preferably at least a factor 4 higher, than the dopant concentration in the first protection region.

8. The optoelectronic semiconductor component according to claim 3,
wherein the first protection region ends within the shielding region.

9. The optoelectronic semiconductor component according to claim 1,
wherein the first protection region is arranged outside a core region.

10. The optoelectronic semiconductor component according to claim 1,
in which the dopant concentration in the second protection region is at least a factor of 2 higher, preferably at least a factor of 4 higher, than the dopant concentration in the first protection region.

11. The optoelectronic semiconductor component according to claim 1,
wherein the first injection region and the second injection region are each based on a material having a composition according to the formula (InGa₁₋ₓAlₓ)_{0.49}P_{0.51}, wherein x=1.

12. The optoelectronic semiconductor component according to claim 1,
wherein the first protection region is doped with one of the following materials: Mg, Zn.

13. The optoelectronic semiconductor component according to claim 1, wherein
the active region is formed as a quantum well structure, preferably as a multi-quantum well structure.

14. The optoelectronic semiconductor component according to claim 1,
wherein the active region is intended to emit an electromagnetic radiation in a wavelength range from 580 nm to 1 μm, preferably in a wavelength range from 580 nm to 660 nm.

15. The optoelectronic semiconductor component according to claim 1,
in which a lateral extension of the semiconductor body is less than 100 μm, preferably less than 50 μm and particularly preferably less than 20 μm.

16. A method for producing an optoelectronic semiconductor component, comprising the steps of:
A) providing a semiconductor body having a first injection region, a second injection region in which a second protection region is formed, and an active region intended to generate electromagnetic radiation and arranged between the first injection region and the second injection region, wherein
the first injection region has a first conductivity type,
the second injection region and the second protection region have a second conductivity type,
a dopant concentration in the second protection region is higher than in the second injection region,
the second protection region is arranged on a side of the second injection region facing away from the active region,
B) applying a mask region on a side of the first injection region facing away from the active region, the mask region having a smaller lateral extension than the first injection region and is arranged centrally on the first injection region, as seen in a top view, and
C) introducing a first dopant material into the first injection region to form a first protection region having the first conductivity type extending along a lateral surface of the semiconductor body from the side of the first injection region opposite to the active region into the second injection region and completely penetrating the active region, wherein a dopant concentration in the first protection region is higher than in the first injection region.

17. The method for producing an optoelectronic semiconductor component according to claim 16,
wherein step C) is performed such that a band gap of the active region in the first protection region is enlarged by quantum well intermixing.

18. The method for producing an optoelectronic semiconductor component according to claim 16,
wherein the introduction of a first dopant material into the first injection region in step C) is performed by diffusion.

19. The method for producing an optoelectronic semiconductor component according to claim 16,
wherein in step A) a semiconductor body is provided which additionally has a shielding region between the first protection region and the second protection region.

20. The method for producing an optoelectronic semiconductor component according to claim 16,
wherein in step C) the introduction of the first dopant material into the first injection region to form a first protection region having the first conductivity type, is performed such, that the first protection region extends along a lateral surface of the semiconductor body from the side of the first injection region facing away from the active region into the shielding region and completely penetrates the active region, wherein a dopant concentration in the shielding region is higher than in the first protection region.
